(19) United States
(12) Patent Application Publication
(10) Pub. No.: US 2026/0144005 A1
(43) Pub. Date: May 21, 2026

(54) SURFACE STRUCTURE OF AN ELECTROSTATIC CHUCK AND METHOD FOR FORMING THE SAME

(71) Applicant: Feedback Technology Corp., Hsinchu City (TW)

(72) Inventors: Tsung-Feng Wu, Hsinchu City (CN); Guo-Yang Ciou, Hsinchu City (TW); Chia-Te Lin, Hsinchu City (TW); Po-Han Chen, Hsinchu City (TW); Po-Chia Huang, Hsinchu City (TW)

(21) Appl. No.: 19/446,013

(22) Filed: Jan. 12, 2026

Related U.S. Application Data
(62) Division of application No. 18/945,027, filed on Nov. 12, 2024.

(30) Foreign Application Priority Data
Dec. 8, 2023 (TW) 112147939

(51) Int. Cl. H10P 72/72; C23C 28/04

(52) U.S. Cl. CPC H10P 72/722; C23C 28/042

(57) ABSTRACT

A method for forming surface structure of electrostatic chuck used in semiconductor manufacturing processes is disclosed. The method includes depositing a first protective coating on a substrate and depositing a second protective coating on the first protective coating. In some embodiments, the first protective coating is formed by thermal spraying and is made from materials selected from groups comprising metal oxides, fluorides, and nitrides. The second protective coating is formed by physical vapor deposition and provides a high-density coating having a higher hardness than the first protective coating. In some embodiments, the second protective coating has a porosity of less than 1%. The resulting surface structure includes the substrate, the first protective coating disposed on the substrate, and the second protective coating disposed on the first protective coating, thereby providing enhanced wear resistance and reducing particulate contamination to improve the performance and lifespan of electrostatic chucks in semiconductor manufacturing.

### FIELD OF THE DISCLOSURE

The present invention generally relates to the field of semiconductor manufacturing equipment. More specifically, it pertains to methods for forming a surface structure of an electrostatic chuck (E-Chuck) used within a semiconductor process chamber.

### BACKGROUND OF THE INVENTION

During the manufacturing process of semiconductor wafers, electrostatic chucks are widely employed in various process chambers to secure wafers in place during operations such as heating, adsorption, and rotation. These E-Chucks typically undergo surface treatments to enhance their performance and durability.

A common surface treatment method is thermal spraying. However, as semiconductor manufacturing technologies advance, the surface treatment requirements for electrostatic chucks have become increasingly stringent. Traditional thermal spraying techniques often result in coatings with insufficient density and hardness, which is a significant drawback. Furthermore, the frequent loading and unloading of wafers can lead to the wear of the E-Chuck's protrusions. This wear, in turn, may cause particulate matter to adhere to the backside of the wafers, adversely affecting the yield of subsequent manufacturing processes.

Another prevalent surface treatment method involves the use of sintering techniques. Although sintered electrostatic chucks offer higher hardness, the overall manufacturing costs of such E-chucks are significantly increased.

Therefore, designing an electrostatic chuck with a surface structure that exhibits high hardness, high density, and excellent wear resistance while maintaining cost-effectiveness remains a challenge for those skilled in the art.

### SUMMARY OF THE INVENTION

The primary objective of the present invention is to provide a method for forming a surface structure of an electrostatic chuck that exhibits high hardness, high density, and excellent wear resistance while also offering reduced manufacturing costs.

In one aspect, the method includes depositing a first protective coating on a substrate of an electrostatic chuck. The first protective coating may be formed using thermal spraying techniques, may be made from materials selected from groups comprising metal oxides, fluorides, and nitrides, and may have a thickness ranging from 100 μm to 250 μm, thereby providing a robust protective barrier against wear, corrosion, and thermal effects.

The method further includes depositing a second protective coating on the first protective coating. The second protective coating may be formed using physical vapor deposition (PVD) techniques to create a high-density and thin coating, with a thickness ranging from 0.5 μm to 20 μm, and having a higher hardness than the first protective coating. In some embodiments, the hardness of the second protective coating ranges from 1000 HV to 1500 HV, thereby providing enhanced wear resistance.

Further distinguishing the present invention, the second protective coating has a lower porosity than the first protective coating. In some embodiments, the porosity of the second protective coating is less than 1%, which helps reduce particulate contamination from the electrostatic chuck to a wafer and improves the yield of subsequent semiconductor manufacturing processes.

In another aspect, the method employs deposition conditions optimized for each layer to achieve the desired thickness and material properties of the respective protective coatings. Accordingly, the formed surface structure comprises the substrate, the first protective coating disposed on the substrate, and the second protective coating disposed on the first protective coating.

By providing the above method and the resulting multi-layer surface structure, the present invention significantly advances electrostatic chuck technology for semiconductor manufacturing by combining high hardness, low porosity, and excellent wear resistance in a cost-effective manner.

The foregoing, as well as additional objects, features and advantages of the invention will be more readily apparent from the following detailed description, which proceeds with reference to the accompanying drawings.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1 illustrates a schematic diagram of the surface structure 10 of an electrostatic chuck embodiment according to the present invention.

FIG. 2 depicts a flowchart of a method for forming the surface structure 10 of the electrostatic chuck.

### DESCRIPTION OF THE PREFERRED EMBODIMENTS

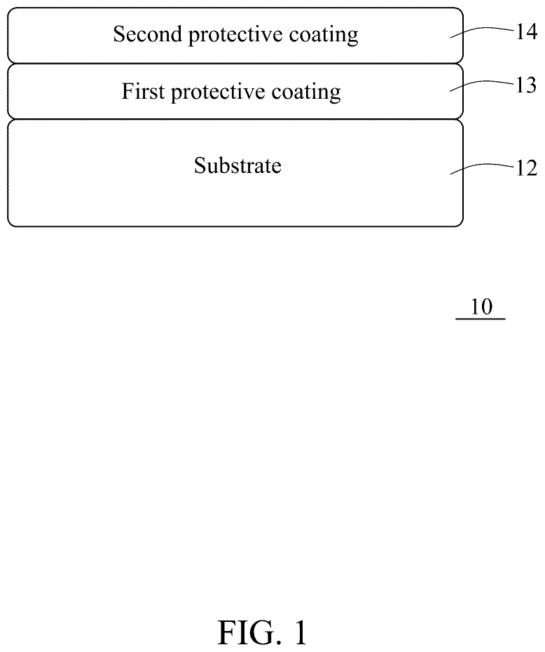

Referring to FIG. 1, FIG. 1 illustrates a schematic diagram of the surface structure 10 of an electrostatic chuck embodiment according to the present invention. The present invention provides an advanced surface structure for an electrostatic chuck, wherein the unique surface structure design is tailored to meet the stringent requirements of modern semiconductor manufacturing processes. The surface structure 10 of the electrostatic chuck in this embodiment comprises three main components: a substrate 12, a first protective coating 13, and a second protective coating 14.

The substrate 12 is typically made from conductive or semiconductor materials capable of generating an electrostatic field, which secures semiconductor wafers in place during various manufacturing processes. In this embodiment, the substrate 12 may be fabricated from aluminum, silicon, or other commonly used metals and ceramic materials in the industry.

The substrate 12 serves as the foundational element of the electrostatic chuck, playing a critical role in the overall performance and functionality of the ESC. Generally, the protective layers are deposited on the substrate 12, which is responsible for generating the electrostatic field that holds the semiconductor wafer in position during the manufacturing process.

In this embodiment, the selection of the substrate 12 material must consider several factors. First, the material must be conductive or semiconductor to generate a sufficient electrostatic field. Common materials include aluminum, silicon, and other metals or ceramics compatible with semiconductor manufacturing environments. Additionally, the material should possess high thermal conductivity to ensure uniform heating of the wafer, thereby maintaining process consistency.

Furthermore, the structural integrity of the substrate 12 is another important consideration. It must be sufficiently robust to withstand mechanical stresses generated during wafer loading and unloading processes, as well as thermal stresses during wafer heating. Moreover, the substrate 12 is typically designed with specific geometries to optimize its mechanical properties, such as tensile strength and fracture toughness.

Additionally, prior to the deposition of protective coatings, the substrate 12 undergoes a series of surface preparation steps. These may include cleaning, etching, and priming to ensure the surface is free from contaminants and conducive to the adhesion of subsequent layers. The surface roughness of the substrate 12 may also be controlled within a specific range to optimize the bond strength between the substrate 12 and the first protective coating 13.

The electrical properties of the substrate 12, such as resistivity and dielectric constant, are also adjusted to optimize the electrostatic holding force. These properties are particularly important when handling ultra-thin or irregularly shaped wafers, as they ensure the wafer remains securely fixed throughout the manufacturing process.

Referring again to FIG. 1, the first protective coating 13 is directly applied to the surface of the substrate 12. The first protective coating 13 serves to protect the substrate 12 from wear and corrosion, thereby extending the lifespan of the electrostatic chuck (ESC).

In this embodiment, the first protective coating 13 is formed using thermal spraying techniques, such as atmospheric plasma spraying (APS), suspension plasma spraying (SPS), or vacuum plasma spraying (VPS). Each method has its own advantages and limitations, and the choice of method typically depends on factors such as the desired coating thickness, porosity, and hardness. The thickness of the first protective coating 13 ranges from 100 μm to 250 μm. This range provides sufficient protection for the substrate 12 while allowing effective heat conduction.

The materials for the first protective coating 13 are selected from groups comprising metal oxides, fluorides, and nitrides, such as TiO₂, Al₂O₃, YF₃, Er₂O₃, Gd₂O₃, Y₂O₃, etc. These materials are renowned for their excellent thermal stability, corrosion resistance, and mechanical properties, making them ideal choices for this application.

The hardness of the first protective coating 13 is designed to be within the range of 400 HV to 700 HV, providing a balance between mechanical strength and flexibility.

Due to the relatively thick nature of the first protective coating 13, thermal spraying techniques are employed to increase the deposition rate. Depending on the process design, the porosity of the first protective coating 13 ranges from 1% to 5%.

The deposition process is meticulously controlled to achieve the desired properties of the first protective coating 13. For example, an arc current ranging from 200 A to 600 A and a rotating disc speed from 5 RPM to 30 RPM may be used. The choice of carrier gas, such as argon, nitrogen, or helium, and its flow rate are also optimized to ensure high-quality deposition.

Through the careful design and implementation of the first protective coating 13, the present invention significantly enhances the performance and lifespan of the electrostatic chuck. The first protective coating 13 possesses sufficient thickness and strength to increase the wear and corrosion resistance of the substrate.

Referring again to FIG. 1, the second protective coating 14 is applied atop the first protective coating 13. The second protective coating 14 is much thinner, with a thickness range from 0.5 μm to 20 μm. Despite its reduced thickness, the second protective coating 14 provides exceptionally high hardness, ranging from 1000 HV to 1500 HV, thereby offering superior wear resistance and reducing the risk of particle contamination.

The second protective coating 14 is formed using Physical Vapor Deposition (PVD) techniques to create a high-density and high-hardness coating. Specifically, the PVD process is highly controlled to achieve the desired properties of the second protective coating 14. Parameters such as chamber temperature, deposition rate, ion source plasma power, and gas flow rate are finely tuned. For example, the chamber temperature may range from 25° C. to 200° C., the deposition rate from 0.1 nm/s to 1.5 nm/s, and other parameters are adjusted accordingly.

Additionally, PVD methods such as electron beam physical vapor deposition (E-Gun PVD) or ion-assisted electron beam physical vapor deposition provide specific advantages in coating quality and process control.

Although the materials for the second protective coating 14 are also selected from groups comprising metal oxides, fluorides, and nitrides, similar to the first protective coating 13, the use of vacuum PVD techniques allows for the production of coatings with higher hardness and lower porosity. The porosity of the second protective coating 14 is designed to be less than 1%, significantly lower than that of the first protective coating 13. This low porosity enhances the hardness and wear resistance of the second protective coating 14, making it ideal for prolonged contact with semiconductor wafers and effectively reducing particle contamination from the E-Chuck to the wafer.

In summary, the second protective coating 14, as the topmost layer in direct contact with the semiconductor wafer, provides exceptionally high hardness, low porosity, and outstanding wear resistance. This enhances the corrosion and wear resistance of the first protective coating 13. Therefore, the surface structure 10 of the electrostatic chuck in this embodiment addresses the shortcomings of existing electrostatic chucks by not only enhancing wear resistance but also significantly reducing the risk of particle contamination, thereby lowering overall manufacturing costs and improving the yield and reliability of the semiconductor manufacturing process.

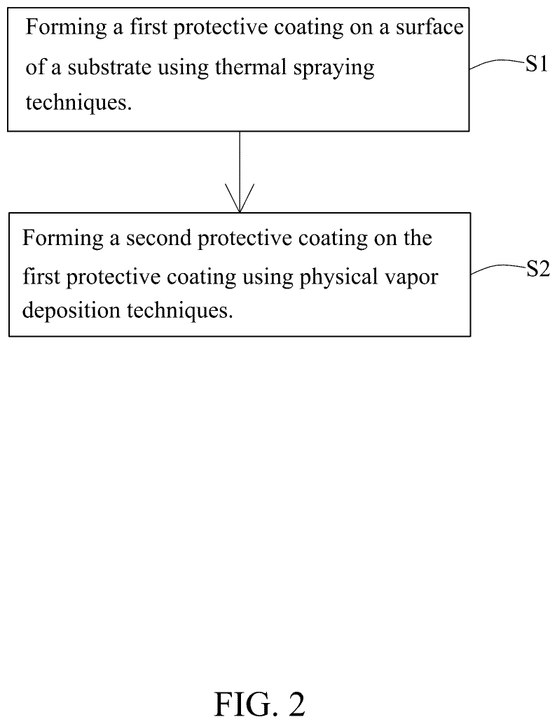

Referring to FIG. 2, FIG. 2 illustrates a flowchart of a method for forming the surface structure 10 of the electrostatic chuck. Below, the manufacturing process of the surface structure 10 of the electrostatic chuck in this embodiment is described in detail.

Firstly, referring to step S1, the first protective coating 13 is deposited on the substrate 12 using thermal spraying techniques under specific conditions, such as atmospheric plasma spraying (APS), suspension plasma spraying (SPS), and vacuum plasma spraying (VPS). The three thermal spraying techniques are detailed as follows:
1. Atmospheric Plasma Spraying (APS): APS is one of the most commonly used techniques for depositing the first protective coating 13. In this method, the coating material is introduced into a high-temperature plasma jet, which melts the particles and propels them toward the substrate 12. APS is typically conducted at atmospheric pressure and is suitable for a wide range of materials, including metal oxides, fluorides, and nitrides. Process parameters such as arc current (200 A-600 A), carrier gas flow rate (30 L/min-200 L/min), and rotating disc speed (5 RPM-30 RPM) can be adjusted to achieve the desired coating properties.
2. Suspension Plasma Spraying (SPS): SPS is a variant of conventional plasma spraying that utilizes a suspension of fine powder particles in a liquid medium. This method allows for the deposition of layers with unique microstructures and enhanced properties. SPS is particularly suitable for depositing coatings with complex compositions, such as mixed oxides. The process conditions are similar to APS but may require additional control to manage the supply rate of the suspension and plasma parameters.
3. Vacuum Plasma Spraying (VPS): VPS is performed in a controlled vacuum environment, minimizing oxidation and contamination during the spraying process. This method is highly suitable for materials sensitive to atmospheric conditions. VPS allows for stricter control over the microstructure and properties of the coating. The vacuum pressure during the process ranges from 5.0×10¹ to 1.0×10⁻² Torr, and the preheating temperature can be set between 100° C. and 300° C. to enhance coating adhesion.

Furthermore, the plasma spraying deposition process is controlled by several parameters to achieve the desired properties of the first protective coating 13. These include an arc current ranging from 200 A to 600 A, a substrate rotation speed from 5 RPM to 30 RPM, and the type of carrier gas, such as argon, nitrogen, or helium. The gas flow rate is adjusted between 30 L/min and 200 L/min, and the process pressure may vary from 1 atmosphere to 1.0×10⁻² Torr. The plasma spraying technique is particularly suitable for depositing thick coatings ranging from 100 μm to 250 μm, thereby providing robust protection for the metal components of the electrostatic chuck.

Additionally, an optional but typically beneficial step in the process is the preheating of the substrate 12. The preheating temperature of the substrate 12 can range from 100° C. to 300° C., which aids in improving the adhesion and density of the deposited layer. Moreover, when the thermal properties of the substrate 12 material differ from those of the coating material, preheating the substrate 12 significantly enhances the adhesion between the substrate 12 and the first protective coating 13.

Subsequently, referring to step S2, the second protective coating 14 is deposited on the first protective coating 13 using Physical Vapor Deposition (PVD) techniques under optimized conditions. The PVD techniques include electron beam physical vapor deposition (E-Gun PVD) and ion-assisted electron beam physical vapor deposition. These PVD methods are detailed as follows:
1. Electron Beam Physical Vapor Deposition (E-Gun PVD): E-Gun PVD is a highly specialized thin-film deposition method. In this technique, an electron beam is used to evaporate the source material, which then condenses on the substrate 12 to form the coating. The process is conducted in a high-vacuum chamber, allowing precise control over the film's microstructure and properties. Deposition conditions can be finely tuned, including chamber temperature (25° C. to 200° C.), deposition rate (0.1 nm/s to 1.5 nm/s), and process pressure (1.0×10⁻² to 1.0×10⁻⁶ Torr). This method is particularly suitable for depositing coatings with high hardness (1000-1500 HV) and low porosity (<1%).
2. Ion-Assisted Electron Beam Physical Vapor Deposition: This is an advanced variant of E-Gun PVD, wherein an ion source assists the deposition process. Ion assistance helps enhance the density, adhesion, and other mechanical properties of the film. Ion source parameters, such as plasma power, electron beam current (0-1500 mA), and voltage (100 V-1500 V), can be adjusted to achieve the desired coating characteristics. The gas flow rates for argon and oxygen can be adjusted between 5 sccm to 50 sccm and 10 sccm to 200 sccm, respectively.

Regardless of whether electron beam physical vapor deposition (E-Gun PVD) or ion-assisted electron beam physical vapor deposition is used, both methods are highly suitable for depositing the second protective coating 14 composed of metal oxides, fluorides, or nitrides, with thicknesses ranging from 0.5 μm to 20 μm.

Furthermore, the optimized conditions mentioned above include chamber temperature, deposition rate, and process pressure. For instance, the chamber temperature ranges from 25° C. to 200° C., the deposition rate from 0.1 nm/s to 1.5 nm/s, and the ion source plasma power can be finely adjusted. Additionally, the electron beam current can range from 0 to 1500 mA, and the voltage from 100 V to 1500 V.

Moreover, the carrier gases used in the PVD techniques, such as argon and oxygen, have flow rates ranging from 5 sccm to 50 sccm and 10 sccm to 200 sccm, respectively, while the process pressure is maintained between 1.0×10⁻² and 1.0×10⁻⁶ Torr. By optimizing the deposition methods, materials, and process parameters under these conditions, the second protective coating 14 is formed with superior properties that exceed the stringent requirements of semiconductor manufacturing, thereby significantly enhancing performance and extending the lifespan of the electrostatic chuck.

Therefore, compared to traditional methods that utilize sintering to form the surface structure of the electrostatic chuck, the present method employs thermal spraying techniques in conjunction with Physical Vapor Deposition (PVD) methods to generate the first protective coating 13 and the second protective coating 14. This approach effectively reduces the cost of manufacturing the surface structure 10 of the electrostatic chuck.

In summary, the present invention provides a surface structure for an electrostatic chuck and its method of formation, which not only meets the performance and durability requirements of contemporary semiconductor manufacturing processes but also surpasses these requirements. Thus, the present invention represents a significant advancement in the field by cost-effectively delivering a combination of high hardness, low porosity, and excellent wear resistance.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for forming a surface structure of an electrostatic chuck, comprising:
forming a first protective coating on a surface of a substrate; and
forming a second protective coating on the first protective coating;
wherein the second protective coating has a hardness greater than the first protective coating, and the porosity of the second protective coating is less than 1%.

2. The method of claim 1, further comprising preheating the substrate to a temperature between 100° C. and 300° C. prior to forming the first protective coating.

3. The method of claim 1, wherein the first protective coating is deposited using one of the following methods: atmospheric plasma spraying, suspension plasma spraying, or vacuum plasma spraying.

4. The method of claim 3, wherein the deposition conditions for the first protective coating are selected from the group consisting of: an arc current between 200 A and 600 A, a rotating disc speed between 5 RPM and 30 RPM, a carrier gas selected from argon, nitrogen, and helium, and a gas flow rate between 30 L/min and 200 L/min.

5. The method of claim 1, wherein the second protective coating is deposited using one of the following methods: electron beam physical vapor deposition (E-Gun PVD) or ion-assisted electron beam physical vapor deposition.

6. The method of claim 5, wherein the deposition conditions for the second protective coating are selected from the group consisting of: a chamber temperature between 25° C. and 200° C., a deposition rate between 0.1 nm/s and 1.5 nm/s, an ion source plasma power assisting an electron beam current between 0 mA and 1500 mA, a voltage between 100 V and 1500 V, an argon gas flow rate between 5 sccm and 50 sccm, an oxygen gas flow rate between 10 sccm and 200 sccm, and a process pressure between 1.0E-2 Torr and 1.0E-6 Torr.

7. The method of claim 1, wherein the porosity of the second protective coating is less than the porosity of the first protective coating.

8. The method of claim 1, wherein the first protective coating is selected from the group consisting of metal oxides, fluorides, and nitrides, and the thickness of the first protective coating is between 100 μm and 250 μm.

9. The method of claim 1, wherein the hardness of the first protective coating is between 400 HV and 700 HV.

10. The method of claim 1, wherein the porosity of the first protective coating is between 1% and 5%.

11. The method of claim 1, wherein the second protective coating is selected from the group consisting of metal oxides, fluorides, and nitrides, and the thickness of the second protective coating is between 0.5 μm and 20 μm.

12. The method of claim 1, wherein the hardness of the second protective coating is between 1000 HV and 1500 HV.
